(19) United States
(12) Patent Application Publication
(10) Pub. No.: US 2002/0162672 A1
(43) Pub. Date: Nov. 7, 2002

(54) Use of doped synthetic polymer materials for packaging of power electric assemblies

(76) Inventors: Derrick E. Cook, Saline, MI (US); Peter A. Hatch, Dearborn Heights, MI (US); Paul William Keberly, Canton, MI (US)

Correspondence Address: SEED INTELLECTUAL PROPERTY LAW GROUP PLLC, 701 FIFTH AVE, SUITE 6300, SEATTLE, WA, 98104-7092, US

(21) Appl. No.: 09/848,700

(22) Filed: May 3, 2001

(51) Int. Cl. H05K 9/00

(52) U.S. Cl. 174/35 R

(57) ABSTRACT

The invention is a doped synthetic polymer material for packaging of power electric assemblies. The polymer provides electromagnetic interference (EMI) shielding using such materials as nickel, carbon fiber, aluminum or other such characteristic elements. The invention provides structural integrity for power electronic packaging, while reducing cost, size, weight and design flexibility over the prior art.

### BACKGROUND OF THE INVENTION

1. Field of the Invention

This present invention generally relates to power electronic enclosures and, more particularly, to an improved enclosure using doped synthetic polymer materials for packaging power electronic assemblies to shield electromagnetic interference (EMI).

2. Discussion of the Prior Art

Electronic devices are becoming more prevalent and more complex. These devices are an integral part of virtually every home and business. Even traditionally mechanical devices, such as automobiles, are incorporating ever larger and more complex electronic elements.

Electronic devices generate and are penetrated by electromagnetic radiation or interference (EMI). The frequencies and amplitudes of the EMI vary depending on the device. In most cases, such EMI is an unwanted by-product of electronic activity. Some EMI interferes with certain parts of the same equipment or with other electronic units located near the equipment.

It is known in the prior art that use of a metallic or electrically conductive enveloping enclosure prevents the transmission of or interference from EMI within a protected space. This is sometimes called an electromagnetic shield. In some cases, this shield is soldered to the electric device. This application often requires attachment points on the circuit and is difficult to remove once installed. Alternatively, when a large area requires protecting, the shield could be cast to accommodate the entire electric circuit or device. These solid, continuous metal enclosures provide a good barrier to EMI. Unfortunately, these enclosures are often costly, heavy, and cumbersome. Thus, the enclosures may interfere with design considerations.

Issues of electromagnetic shield cost, weight, size, and design are also addressed to some extent in the prior art. For example, U.S. Pat. No. 4,890,199 (Beutler) provides a space saving electromagnetic shield. The shield uses a conductive material having opposing cantilever spring fingers that can be easily removed. This permits assembly by using automatic manufacturing processes. This invention is particularly adapted to miniature electronic equipment such as portable telephones because an object of the invention was to use as little shielding space as possible.

U.S. Pat. No. 5,353,201 (Maeda) provides an EMI shield device that can attach to a printed circuit board having electrical components. The shield body is made of a material of desired magnetic permeability. The invention uses a plurality of legs that penetrate a slit on the printed circuit board. Its construction, therefore, does not require a large number of sites to be connected by soldering or welding. U.S. Pat. No. 5,684,340 (Soler, et al.) provides an arrangement of components that form an EMI shield that allows signal or power conductors to pass through the enclosure without compromising the effectiveness of the shield. The invention envisages conducting zones, arranged on the faces of the printed circuit board, interacting with a conductive joint that provides good electrical contact with the conductive protective enclosure. An object of the Soler et al. invention is the use of standard, cheap and easily assembled parts.

EMI shields composed of polymers are also known in the prior art. U.S. Pat. No. 5,571,991 (Highum et al.) discusses a shield for housing electronic components and providing a barrier to electromagnetic radiation. The enclosure has three layers. The outer and inner surface are of a polymeric base material in which is suspended an electrically conductive fill material, giving the layers high electrical conductivity. The middle layer is a polymeric base material suspended with fill material having high magnetic permeability. The resultant molded structure can be made inexpensively in a single co-injection molding operation.

Prior art plastic EMI shields with a metal inner surface to prevent EMI are also known in the prior art. The metal film is prepared by using surface treatment techniques such as plating, coating, depositing and flame coating. For example, U.S. Pat. No. 5,841,067 (Nakamura et al.) provides a housing sheet molded from magnetic material containing a specific resin composition with the interior surface lined with a conductive material. Unfortunately, in a high-density compact area, such as small electronic equipment, this can result in short circuits because of the small distance between components of the circuit and the metal film.

U.S. Pat. No. 5,867,370 (Masuda) discloses a plastic EMI shield using a conductive resin covered by a nonconductive resin. Other plastic shielding devices have developed. U.S. Pat. No. 5,137,782 (Adriaenson et al.) provides a granular composite having metal fibers for incorporation into resins. Various EMI shielding characteristics are obtained using different processing conditions. See also, generally U.S. Pat. No. 5,827,997 (Chung et al.).

In summary, prior art power electronic packaging is dominated by metallic enclosures that provide mechanical integrity, environmental sealing, and EMI shielding. Metallic based enclosures are typically costly, heavy and do not offer a high degree of freedom with regard to packaging form and are corrosive. Other solutions in the prior art attempt to solve these problems using polymer housings combined with metal films or metal composites. Although lightweight, these shields add considerable cost.

Therefore, there is a need for a unique packaging solution for power electronic assemblies, particularly in automobiles, that would yield lower cost, lighter weight, flexible packaging, and EMI shielding capability.

### SUMMARY OF THE INVENTION

Accordingly, an object of the present invention is to provide doped synthetic polymer materials for packaging of power electric assemblies.

It is a further object of the present invention to provide a doped synthetic polymer that provides electromagnetic interference (EMI) shielding.

It is a further object of the present invention to provide a doped synthetic polymer that provides electromagnetic interference (EMI) shielding using such materials as nickel, carbon fiber, aluminum or other such characteristic elements

It is a further object of the present invention to provide a doped synthetic polymer that provides structural integrity for power electronic packaging.

It is a further object of the present invention to provide a doped synthetic polymer that provides reduced cost, size, weight and design flexibility over the prior art.

Other objects of the present invention will become more apparent to persons having ordinary skill in the art to which the present invention pertains from the following description taken in conjunction with the accompanying figures.

### BRIEF DESCRIPTION OF THE FIGURES

The foregoing objects, advantages, and features, as well as other objects and advantages, will become apparent with reference to the description and figures below, in which like numerals represent like elements and in which:

FIG. 1 shows a perspective view of the illustrated embodiment.

FIG. 2 shows a cross-section of the illustrated embodiment.

FIG. 3 shows a perspective view of the lower portion of the illustrated embodiment.

### DETAILED DESCRIPTION OF THE PREFERRED EMBODIMENT

The present invention provides a unique packaging solution using plastic polymer blends to provide electromagnetic interference (EMI) shielding and structural integrity. The illustrated embodiment provides a doped synthetic polymer that provides reduced cost, size, and weight while also offering variable degrees of EMI shielding for packaging of power electronic modules and associated EMI radiating electronic assemblies.

The advantages of the doped synthetic polymer of the present invention make it especially suited for automotive applications although other applications are possible. Synthetic polymers are very durable and able to withstand the often harsh environmental conditions experienced by an automobile. Injection molding to produce such polymers allows use of inexpensive raw materials while providing great design form flexibility. Design flexibility is critical to most automotive applications given the often-limited space availability. A doped synthetic polymer can provide EMI shielding and is non-corrosive. And finally, a doped synthetic polymer can reduce labor cost over prior art EMI solutions by having fewer parts to assemble.

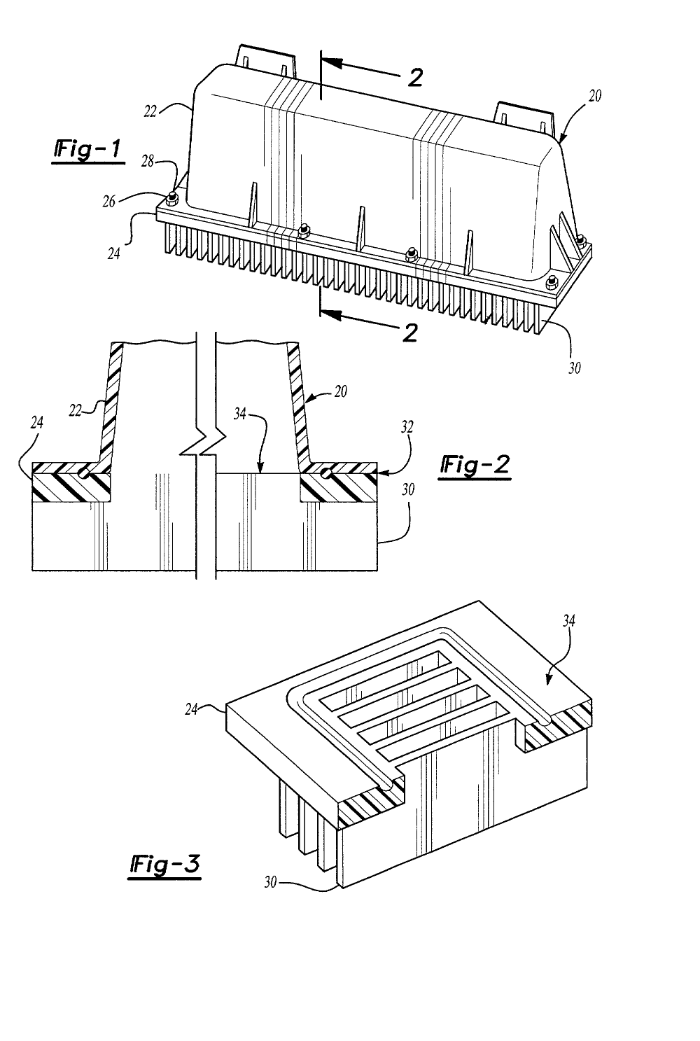

The illustrated embodiment, shown in FIGS. 1 and 2, is an enclosure 20 for an automotive packaging of electronic modules although several various configurations could be possible to one skilled in the art. The enclosure 20 is a polymer based material doped with such materials as nickel, carbon fiber, aluminum or other such characteristic elements that provide not only mechanical integrity but also sealing, various EMI shielding and design flexibility.

Enclosure 20 has a housing 22 and a thermal-conductive plate 24 that attach using various means. The housing 22 is shaped to cover the power electronics (not shown) having an open end with a flat edge 32. The plate 24 has a matching flat edge 34 to receive and seal against the housing flat edge 32. The plate 24 can be made from a variety of thermal-conductive materials such as aluminum and is shown in more detail in FIG. 3. The plate 24 can be of sufficient thickness to allow even distribution of cooling capacity. FIG. 1 illustrates the attachment of the housing 22 to the plate 24 using at least one nut 26 and one bolt 28, although many other types of fasteners would be acceptable. An alternate embodiment could allow the plate 24 to be insert molded directly into the housing 22 using a process well known in the prior art. Plate 24 also has heat-dissipating fins 30 whereby the housed electronics (not shown) are cooled to assure optimal operating conditions.

The above-described embodiment of the invention is provided purely for purposes of example. Many other variations, modifications, and applications of the present invention may possible.

I claim:

1. A synthetic polymer material for packaging power electric assemblies.

2. The synthetic polymer material of claim 1 further comprising a material to provide electromagnetic interference (EMI) shielding.

3. The synthetic polymer material of claim 2 wherein the EMI shielding material is nickel.

4. The synthetic polymer material of claim 2 wherein the EMI shielding material is carbon fiber.

5. The synthetic polymer material of claim 2 wherein the EMI shielding material is aluminum.

6. A power electronics assembly using a doped synthetic polymer comprising:
a housing shaped to cover the power electronics comprising an open end with a flat edge;
a thermal-conductive plate comprising a flat edge to match and seal against the housing flat edge; and
an attachment means to attach the housing and plate.

7. The assembly of claim 6 wherein the attachment means is by at least one bolt and at least one nut.

8. The assembly of claim 6 wherein the attachment means is by insert molding the plate to the housing.

9. The assembly of claim 6 wherein the plate is aluminum.

10. The assembly of claim 6 wherein the plate is of sufficient thickness to allow even distribution of cooling capacity.

11. The assembly of claim 6 wherein the housing provides electromagnetic interference (EMI) shielding.
